(19) United States
(12) Patent Application Publication
(10) Pub. No.: US 2009/0096009 A1
(43) Pub. Date: Apr. 16, 2009

(54) NONVOLATILE MEMORIES WHICH COMBINE A DIELECTRIC, CHARGE-TRAPPING LAYER WITH A FLOATING GATE

(75) Inventors: Zhong Dong, Fremont, CA (US); Chiliang Chen, Sunnyvale, CA (US); Ching-Hwa Chen, Milpitas, CA (US)

Correspondence Address: MACPHERSON KWOK CHEN & HEID LLP, 2033 GATEWAY PLACE, SUITE 400, SAN JOSE, CA, 95110, US

(73) Assignee: ProMOS Technologies Pte. Ltd.

(21) Appl. No.: 11/872,998

(22) Filed: Oct. 16, 2007

(51) Int. Cl. H01L 29/788; H01L 21/336

(52) U.S. Cl. 257/321; 438/264; 257/E29.304; 257/E21.422

(57) ABSTRACT

A nonvolatile memory cell stores at least 50% of the charge in a dielectric, charge-trapping layer (160) and at least 20% of the charge in a floating gate (170). The floating gate is at most 20 nm thick.

### BACKGROUND OF THE INVENTION

The present invention relates to nonvolatile memories which store electric charge to define the memory state.

A nonvolatile memory may have a charge storage element for storing charge to define the memory state. The charge storage element can be conductive (a floating gate) or dielectric (a charge trapping element). In either case, the charge storage capacity of the charge storage element must be sufficiently large to allow fast, reliable reading of the memory state. Floating gates are typically made of doped polysilicon, and the polysilicon thickness of 100 nm or higher is not unusual to provide sufficient charge storage capacity. This large thickness is an impediment to scaling the memory area because the thickness-to-width ratio of the floating gate becomes high when the width is reduced, and the memory becomes more difficult to fabricate. In addition, the tunnel dielectric has to be fairly thick (typically above 6 nm for silicon dioxide) to provide good retention of the highly mobile charge on the floating gate. In contrast, charge trapping memories do not require a thick tunnel dielectric, and a charge trapping element (e.g. a silicon nitride layer) is usually thinner than a typical floating gate, but the charge storage capacity of the charge trapping elements is typically lower than for the floating gates. To increase the charge storage capacity (measured sometimes as the charge trapping density), the dielectric of the charge storage element can be embedded with nanocrystals made of cobalt, gold, or some other material. See U.S. patent application Ser. No. 11/131,006 filed May 17, 2005 by Bhattacharyya, published as no. 2006/0261401 on Nov. 23, 2006. Alternatively, the charge trapping layer may include a silicon layer sandwiched between two silicon nitride layers to provide additional charge trapping sites at the interface between the silicon layer and the silicon nitride layers (U.S. Pat. No. 6,936,884 B2, published Aug. 30, 2005). In a floating gate memory, the charge storage capacity can be increased by providing dielectric regions inside the floating gate (U.S. patent application Ser. No. 11/155,197 filed Jun. 17, 2005 by Mouli et al., published as no. 2006/0286747 on Dec. 21, 2006).

Improved charge storage elements are desirable.

### SUMMARY

This section summarizes some features of the invention. Other features are described in the subsequent sections. The invention is defined by the appended claims, which are incorporated into this section by reference.

In some embodiments of the present invention, the charge storage element includes both a charge trapping layer and a conductive layer (i.e. a floating gate). The floating gate serves as a charge tank to enhance the charge storage capacity of the charge trapping layer. Therefore, the floating gate thickness can be reduced. A range of 1 to 20 nm is believed to be suitable.

In some embodiments, 50% to 80% of the charge stored in a memory cell is stored in the charge trapping layer, and the remaining 50% to 20% is stored on the floating gate.

The charge is tunneled in and out of the memory through a tunnel dielectric adjacent to the charge trapping layer. The floating gate is separated from the tunnel dielectric by the charge trapping layer, so the tunnel dielectric can be as thin as in a conventional charge trapping memory (e.g. 3 nm silicon dioxide; other materials can also be used).

The invention is not limited to the features and advantages described above. Other features are described below. The invention is defined by the appended claims.

### BRIEF DESCRIPTION OF THE DRAWINGS

FIG. 1 shows a cross section of a memory cell according to some embodiments of the present invention.

FIG. 2 is a block diagram of a voltage generator for use in some embodiments of the present invention.

FIGS. 3 and 4 are energy band diagrams for some embodiments of the present invention.

### DESCRIPTION OF SOME EMBODIMENTS

The embodiments described in this section illustrate but do not limit the invention. In particular, the invention is not limited to specific dimensions, materials, or modes of operation except as defined by the appended claims.

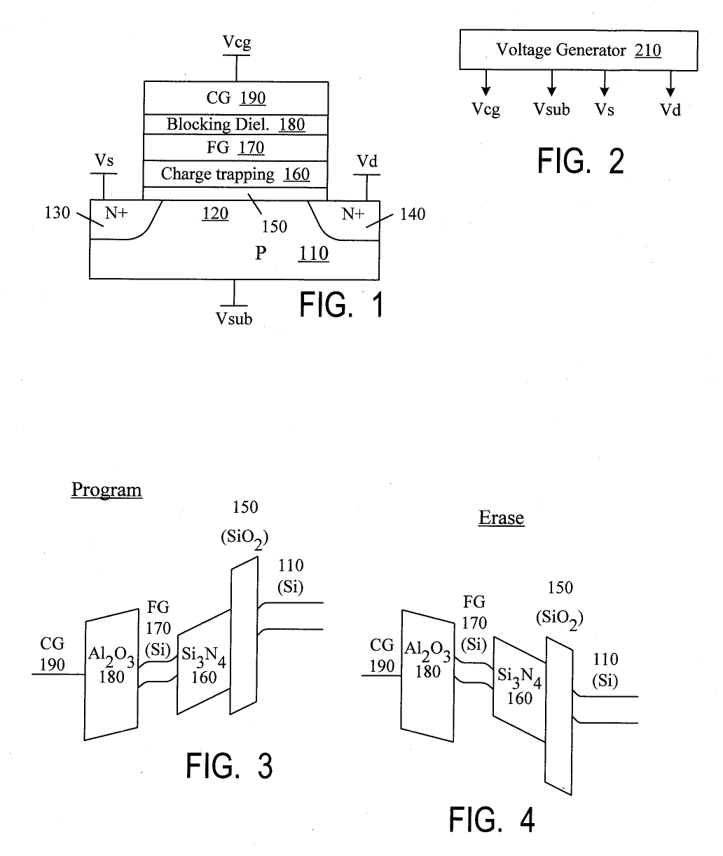

FIG. 1 shows a vertical cross section of a nonvolatile memory cell according to some embodiments of the present invention. The cell's active area is a semiconductor region which is part of a semiconductor substrate 110. Substrate 110 can be monocrystalline silicon or some other suitable material. The active area includes a P-type channel region 120 and N-type source/drain regions 130, 140 (the P and N conductivity types can be reversed). For ease of reference, the region 130 will be called “source”, and the region 140 will be called “drain”. In fact, in some embodiments each of regions 130, 140 can act as a source or a drain in the same cell in different modes of operation.

Tunnel dielectric 150 is formed directly on the active area over the channel region 120 and over all or part of source/drain regions 130, 140. In some embodiments, tunnel dielectric 150 is a layer of silicon dioxide, or silicon nitride, or titanium oxide, or a combination of these materials, or some other suitable material. See e.g. the aforementioned U.S. patent application published as 2006/0261401 A1, which is incorporated herein by reference. A layer of silicon dioxide of 3 nm thickness is believed to be suitable, and thicker or thinner layers (e.g. 1 nm to 6 nm) can be used. Charge trapping layer 160 is formed directly on dielectric 150. In some embodiments, layer 160 is silicon nitride (possibly silicon-rich silicon nitride) which is 4 nm to 14 nm thick. This thickness is not limiting. Other possible materials include silicon oxynitride, tantalum nitride, tantalum oxide, aluminum nitride, and possibly others. In some embodiments, the layer 160 will store 50% to 80% of the total charge stored in the memory cell when the cell is programmed.

Floating gate 170 is formed directly on charge trapping layer 160 from a suitable conductive material, e.g. doped polysilicon, metal, or a conductive silicide. The thickness of floating gate 170 is at most 20 nm. Lower thickness values, e.g. 1 nm, can also be used. In some embodiments, floating gate 170 stores 20% to 50% of the charge when the memory cell is programmed.

Blocking dielectric 180 is formed directly on floating gate 170. In some embodiments, blocking dielectric 180 is silicon dioxide, silicon nitride, aluminum oxide, or some other dielectric.

Control gate 190 is a conductive layer (e.g. metal) formed directly on blocking dielectric 180.

Voltage generator 210 (FIG. 2) can be a conventional circuit which generates a voltage Vcg for control gate 210, a voltage Vsub for substrate 110, a voltage Vs for source region 130, and a voltage Vd for drain region 140. Voltage generator 210 can be part of the same integrated circuit as the memory cell. Alternatively, all or part of the voltage generator can be external to the integrated circuit.

The memory cell can be operated in the same manner as conventional charge-trapping cells or floating gate cells. For example, the memory cell can be programmed by providing the voltage Vcg of 10V to 13V on control gate 190 and providing the ground voltage Vsub on substrate 110. The source/drain regions 130, 140 float. As a result, charge trapping element 160 and floating gate 170 become negatively charged. It is believed that the negative charge (e.g. conduction and/or valence band electrons) is transferred from channel region 120 through tunnel dielectric 150 into the conduction band of layer 160, and some of the electrons get trapped in layer 160 while others reach the floating gate 170. However, the invention does not depend on any particular theory of operation except as defined by the claims.

FIG. 3 is an energy band diagram for this programming operation assuming that substrate 110 is monocrystalline silicon, tunnel dielectric 150 is silicon dioxide, charge trapping layer 160 is silicon nitride, floating gate 170 is doped polysilicon, blocking dielectric 180 is aluminum oxide, and control gate 190 is tantalum. The band-gap energy range of substrate 110 (i.e. the energies between the valence band and the conduction band) is entirely within the band-gap energy range of tunnel dielectric 150. The band-gap energy range of dielectric 150 contains the band-gap energy range of charge trapping dielectric 160, which contains the band-gap energy range of floating gate 170, which is within the band-gap energy range of blocking dielectric 180, which contains the Fermi level of control gate 190.

The memory is erased by supplying a voltage Vsub of 8V to 11V to substrate 110 while holding the control gate at ground. The source/drain regions 130, 140 float. The negative charge in floating gate 170 and charge trapping layer 160 is erased, perhaps by tunneling of conduction-band and/or valence-band electrons into channel 120.

FIG. 4 is an energy band diagram for the erase operation for the same materials as in FIG. 3.

The memory cell can be read by providing a voltage difference between the source/drain regions 130, 140 and driving the control gate 190 to a voltage level which is between threshold voltages of the memory cell in the programmed and the unprogrammed states.

The memory cell can be fabricated using known techniques. In some embodiments, a P well is provided in substrate 110, then dielectric 150 is formed on the P well, then charge trapping layer 160 is formed, then floating gate layer 170 is formed, then blocking dielectric 180 is formed, then control gate layer 190 is formed. Possibly additional layers are formed over the layer 190. The layers are patterned at suitable stages of fabrication. Source/drain regions 130, 140 are doped as needed.

The invention is not limited to the embodiments described above. In some embodiments, the memory cell is programmed by hot electron injection. The memory cell can be a multi-state cell, possibly with multiple floating gates and multiple charge trapping elements. The memory cell can be part of a memory array. Many memory array and memory cell architectures commonly used for floating gate memories can also be used in conjunction with the present invention. In particular, non-planar memory cells, split-gate memory cells, NAND, AND, NOR and other arrays can be used. Tunnel dielectric 150 may include silicon nitride and/or silicon oxynitride and/or multiple layers with different energy gaps. Charge trapping dielectric 160 can be made of materials other than silicon nitride, and can be embedded with nanocrystals and/or implemented as a combination of layers with different energy bands. The invention is not limited to planar structures. For example, the floating gate, the charge-trapping layer, and the tunnel dielectric may be formed as conformal layers over sidewalls of a protrusion (a fin) in substrate 110 or over sidewalls of a trench in substrate 110.

Some embodiments include an integrated circuit comprising a nonvolatile memory cell comprising a semiconductor region for providing electric charge for altering a state of the nonvolatile memory cell. The semiconductor region can be substrate 110, or channel region 120, or source/drain regions 130, 140. The integrated circuit also comprises a dielectric, charge-trapping layer (e.g. layer 160) for trapping and storing electric charge to define the state of the nonvolatile memory cell; a tunnel dielectric (e.g. 150) separating the semiconductor region from the dielectric, charge-trapping layer; and a floating gate separated from the semiconductor region by the tunnel dielectric and the dielectric, charge-trapping layer, for storing charge to define the state of the nonvolatile memory cell, the floating gate being a layer at most 20 nm thick.

In some embodiments, the dielectric, charge-trapping layer is embedded with conductive or semiconductor particles.

Some embodiments provide an integrated circuit comprising a nonvolatile memory cell comprising: a dielectric, charge-trapping layer, for storing at least part of a charge defining a state of the nonvolatile memory cell; and a floating gate overlying and physically contacting the dielectric, charge-trapping layer; wherein the memory cell has a state defined by a non-zero charge stored in the dielectric, charge-trapping layer and the floating gate, with at least 50% of the non-zero charge stored in the dielectric, charge-trapping layer and at least 20% of the non-zero charge stored in the floating gate.

Other embodiments and variations are within the scope of the invention, as defined by the appended claims.

1. An integrated circuit comprising a nonvolatile memory cell comprising:
a semiconductor region for providing electric charge for altering a state of the nonvolatile memory cell;
a dielectric, charge-trapping layer for trapping and storing electric charge to define the state of the nonvolatile memory cell;
a tunnel dielectric separating the semiconductor region from the dielectric, charge-trapping layer; and
a floating gate separated from the semiconductor region by the tunnel dielectric and the dielectric, charge-trapping layer, for storing charge to define the state of the nonvolatile memory cell, the floating gate being a layer at most 20 nm thick.

2. The integrated circuit of claim 1 wherein the memory cell has a state defined by a non-zero charge stored in the dielectric, charge-trapping layer and the floating gate, with at least 50% of the non-zero charge stored in the dielectric, charge-trapping layer and at least 20% of the non-zero charge stored in the floating gate.

3. The integrated circuit of claim 1 further comprising:
a control gate separated from the semiconductor region by the floating gate, the dielectric, charge-trapping layer and the tunnel dielectric; and
a blocking dielectric separating the floating gate from the control gate.

4. The integrated circuit of claim 1 wherein the semiconductor region comprises a channel region and source/drain regions of the memory cell.

5. The integrated circuit of claim 1 wherein the dielectric, charge-trapping layer is embedded with conductive or semiconductor particles.

6. The integrated circuit of claim 1 wherein the floating gate is at least 1 nm thick.

7. An integrated circuit comprising a nonvolatile memory cell comprising:
a dielectric, charge-trapping layer, for storing at least part of a charge defining a state of the nonvolatile memory cell; and
a floating gate overlying and physically contacting the dielectric, charge-trapping layer;
wherein the memory cell has a state defined by a non-zero charge stored in the dielectric, charge-trapping layer and the floating gate, with at least 50% of the non-zero charge stored in the dielectric, charge-trapping layer and at least 20% of the non-zero charge stored in the floating gate.

8. The integrated circuit of claim 7 further comprising:
a semiconductor region for providing electric charge for altering the memory cell's state; and
a tunnel dielectric separating the semiconductor region from the dielectric, charge-trapping layer.

9. The integrated circuit of claim 8 further comprising a control gate separated from the semiconductor region by the floating gate, the dielectric, charge-trapping layer and the tunnel dielectric; and
a blocking dielectric separating the floating gate from the control gate.

10. A method for fabricating an integrated circuit comprising a nonvolatile memory cell, the method comprising:
forming a tunnel dielectric for the nonvolatile memory cell on a semiconductor region providing a portion of the nonvolatile memory cell;
forming a dielectric, charge-trapping layer for the nonvolatile memory cell on the tunnel dielectric; and
forming a floating gate for the nonvolatile memory cell on the charge-trapping layer, the floating gate being at most 20 nm thick.

11. The method of claim 10 wherein the memory cell has a state defined by a non-zero charge stored in the dielectric, charge-trapping layer and the floating gate, with at least 50% of the non-zero charge stored in the dielectric, charge-trapping layer and at least 20% of the non-zero charge stored in the floating gate.

12. The method of claim 10 further comprising forming a control gate for the nonvolatile memory cell over the floating gate.

13. The method of claim 10 wherein the floating gate is at least 1 nm thick.

14. The method of claim 13 wherein the floating gate is made of doped polysilicon.
